(19) United States
(12) Patent Application Publication
(10) Pub. No.: US 2015/0130460 A1
(43) Pub. Date: May 14, 2015

(54) METHODS FOR SEPARATING OIL AND WATER ON MULTIDIMENSIONAL NUCLEAR MAGNETIC RESONANCE MAPS

(71) Applicant: SCHLUMBERGER TECHNOLOGY CORPORATION, Sugar Land, TX (US)

(72) Inventors: Andrea Valori, Al-Khobar (SA); Mohammed Badri, Al-Khobar (SA); Reza Taherian, Al-Khobar (SA); Wael Abdallah, Dhahran (SA)

(21) Appl. No.: 14/536,823

(22) Filed: Nov. 10, 2014

Related U.S. Application Data
(60) Provisional application No. 61/903,637, filed on Nov. 13, 2013.

(51) Int. Cl. G01R 33/48

(52) U.S. Cl. CPC G01R 33/4828
USPC 324/309

(57) ABSTRACT

Methods are provided for separating oil and water signals in multidimensional nuclear magnetic resonance (NMR) maps. In one embodiment, separate multidimensional NMR maps are provided for oil and water content. In another embodiment, an oil-water boundary and a water-gas boundary are generated on a D-T₂ map. The boundaries may be curved boundaries or lines.

### CROSS REFERENCE TO RELATED APPLICATIONS

This application claims priority to U.S. Provisional Patent Application No. 61/903,637, filed Nov. 13, 2013, the entire disclosure of which is hereby expressly incorporated by reference herein.

### TECHNICAL FIELD

The subject disclosure relates to methods for separating water and oil in multidimensional nuclear magnetic resonance (NMR) maps. More particularly, the subject disclosure relates to methods for processing NMR data and separating water and oil and optionally gas on a multidimensional map such as a Diffusion (D)-T₂ relaxation time map. The subject disclosure has particular application to the hydrocarbon industry, although it is not limited thereto.

### BACKGROUND

Nuclear magnetic resonance (NMR) is a useful tool in the determination of the nature of geological formations. More specifically, NMR tools in boreholes traversing earth formations are able to generate fields that result in signals indicating the presence of water and hydrocarbon in the formation. If the signals from water and hydrocarbons can be separated, hydrocarbon-bearing zones may be identified. Various methods have been proposed for separately identifying water and hydrocarbon signals.

The differential spectrum (DSM) and shifted spectrum (SSM) methods proposed by Akkurt et. al. in “NMR Logging of Natural Gas Reservoirs” Paper N. Transactions of the Society of Professional Well Log Analysts (SPWLA) Annual Logging Symposium, 1995, compare T₂ distributions derived from two Carr-Purcell-Meiboom-Gill (CPMG) measurements performed with different polarization times (DSM) or echo-spacings (SSM). A modification to these methods, known as time domain analysis (TDA), was later introduced by Prammer et al. in “Lithology-Independent Gas Detection by Gradient-NMR Logging,” SPE paper 30562, 1995. In TDA, “difference” data are computed directly in the time domain by subtracting one set of the measured amplitudes from the other. The difference dataset is then assumed to contain light oil and/or gas. In TDA, relative contributions from light oil or gas are derived by performing a linear least squares analysis of the difference data using assumed NMR responses for these fluids. Both DSM and TDA assume that the Water signal has substantially shorter Tₗ relaxation times than those of the hydrocarbons. This assumption is not always valid, however. Most notably, this assumption fails in formations where there are large pores or where the hydrocarbon is of intermediate or high viscosity. The SSM method and its successor, the enhanced diffusion method (EDM) proposed by Akkurt et. al. in “Enhanced Diffusion: Expanding the Range of NMR Direct Hydrocarbon Typing Applications”, Paper GG. Transactions of the Society of Professional Well Log Analysts (SPWLA) Annual Logging Symposium, 1998, separate gas, oil and water contributions based on changes in the T₂ distributions that result from changes in the echo spacing of CPMG measurements. A strategy for combining and selecting these different NMR methods has been described by Coates et al. in U.S. Pat. No. 6,366,087 which is hereby incorporated by reference herein in its entirety.

The diffusion-editing (DE) pulse sequence by Hurlimann et al. provides a different approach. See M. D. Hürlimann et al., “Diffusion-Editing: New NMR Measurement of Saturation and Pore Geometry,” paper presented at the 2002 Annual Meeting of the Society of Professional Well Log Analysts, Osio, Japan, June 2-5; see also, U.S. Pat. No. 6,570,382 to Hürlimann which is hereby incorporated by reference herein in its entirety.

In addition to DE sequences, specialized interpretation methods have been developed for NMR data in order to further enhance hydrocarbon detection. These methods typically apply forward modeling to suites of NMR data acquired with different parameters. The suite of NMR data are typically acquired with different echo spacings (Tₑ) or polarization times (W_{T}), and sometimes acquired with different magnetic field gradients (G). DE sequences are one example of such data acquisition. Two example methods include: the MACNMR proposed by Slijkerman et al., SPE paper 56768, “Processing of Multi-Acquisition NMR Data” (1999), and the Magnetic Resonance Fluid characterization (MRF) method disclosed in U.S. Pat. No. 6,229,308 to Freedman which is hereby incorporated by reference herein in its entirety.

The MRF method is capable of obtaining separate oil and water T₂ distributions. The MRF method may use a Constituent Viscosity Model (CVM), which relates relaxation time and diffusion rates to constituent viscosities whose geometric mean is identical to the macroscopic fluid viscosity. With the MRF method, estimates for water and hydrocarbon volumes are obtained by applying a forward model to simulate the NMR responses to a suite of NMR measurements acquired with different parameters. Specifically, the MRF technique is based on established physical laws which are calibrated empirically to account for the downhole fluid NMR responses. By using realistic fluid models, MRF aims to minimize the number of adjustable parameters to be compatible with the information content of typical NMR log data. Since the model parameters are by design related to the individual fluid volumes and properties, determination of the parameter values (i.e. data-fitting) leads directly to estimates for petrophysical quantities of interest.

Another approach based on a maximum entropy principle (MEP) involves a general model-independent method to analyze complex fluids data acquired with NMR logging instruments and present the results in a visually attractive and easy-to-understand format, hereby referred to as Diffusion-Relaxation maps, or D-T₂ maps. These maps have been used to understand cases where model-based analysis gives unsatisfactory results because of deviations of NMR properties from the “ideal” behavior assumed in the models. These situations can arise due to anomalous fluid/rock interactions such as restricted diffusion, mixed-Wettability and internal gradients. Deviations from the default properties have also been observed for certain crude oils, leading to inaccurate predictions in the model analysis. Through the use of D-T₂ maps, the MEP approach provides a simple graphical representation of the data that can be used to identify fluid responses in different environments. Diffusion-Relaxation maps are further described in U.S. Pat. No. 6,570,382 to Hürlimann et al., and U.S. Pat. No. 6,462,542 to Venkataramanan et al., which are both hereby incorporated by reference herein in their entireties.

In U.S. Pat. No. 7,388,374 to Minh et al., which is hereby incorporated by reference herein in its entirety, a method is disclosed for interpretation of multi-dimensional nuclear magnetic resonance data taken on a sample of an earth formation. Specifically, a set of NMR data is acquired for a fluid sample located either in a borehole or in a laboratory environment. From the set of NMR data, a multi-dimensional distribution is calculated using a mathematical inversion that is independent of prior knowledge of fluid sample properties. The multi-dimensional distribution is graphically displayed on a multi-dimensional map. Each fluid instance or artifact visible on the graph is identified as representing a probable existence of a detected fluid. One or more quantitative formation evaluation answers for one or more fluid instances are computed based on the multi-dimensional distribution associated with the respective fluid instance. In one aspect, quantitative formation evaluation answers may be determined from the multi-dimensional distribution of NMR data by initially determining a set of model parameters which represent aspects of the multi-dimensional distribution. A model dependent inversion may then be applied to compute the fluid properties. In another aspect, quantitative formation evaluation answers may be determined from the multi-dimensional distribution of NMR data by determining a mean diffusion value across a region of a diffusion-T₂ relaxation distribution. The mean diffusion may then be used to determine properties of the fluid associated with the selected region.

### SUMMARY

This summary is provided to introduce a selection of concepts that are further described below in the detailed description. This summary is not intended to identify key or essential features of the claimed subject matter, nor is it intended to be used as an aid in limiting the scope of the claimed subject matter.

Methods are provided for separating oil and water in multidimensional nuclear magnetic resonance (NMR) maps. In one embodiment, a method for separating oil and water in multidimensional NMR maps includes generating individual multidimensional NMR maps for the oil and the water. In one embodiment, a method for separating oil and water in multidimensional NMR maps includes showing separate oil and water domains on a D-T₂ map.

In one embodiment, individual D-T₂ maps for oil and water are generated by processing NMR data in order to generate separate T₂ intensity graphs for the oil and water (e.g., using magnetic resonance fluid (MRF) processing), processing the NMR data to obtain a multidimensional D-T₂ crossplot map, generating diffusion (D) intensity values for each T₂ value, summing a plurality of D intensity values until the sum equals a corresponding value for that T₂ for each of oil and water as set forth, e.g., in the MRF processing, and using that summation for each T₂ value to generate the individual D-T₂ maps.

In one embodiment, the summing of a plurality of D intensity values is accomplished for each T₂ value of interest, by starting with a lowest diffusion bin, and integrating the D signal from that lower limit to a higher limit which is determined when the integrated signal equals the value for oil obtained by, e.g., MRF processing, thereby generating a D-T₂ plot for oil. Then, for water, for the T₂ values of interest, the D intensity value signal is integrated from a lower limit equal to the higher limit of oil to a higher limit for the water which is determined when that integrated signal equals the value for water obtained by, e.g., MRF processing, thereby generating a D-T₂ plot for water. In one embodiment, the D-T₂ plots for water and oil may be applied to the D-T₂ map representing the NMR data.

In one embodiment, methods are extended to separating oil, water and gas. In one aspect, it is assumed that any signal in excess of the water signal is due to gas.

In one aspect, the D-T₂ plots for water and oil when applied to the D-T₂ map representing the NMR data may be considered cutoff lines (curves), such that it is implied that there is no oil above the oil cutoff line (curve), and that there is no water above the water cutoff line (curve) and below the oil cutoff line (curve).

In another aspect, straight oil and water cutoff lines are generated by using known fluid saturations, drawing horizontal lines on the D-T₂ map, integrating fluid volume below and above the line, and adjusting the line locations until the fluid volumes equal the known saturation levels.

Additional aspects, embodiments, and advantages of the disclosed methods may be understood with reference to the following detailed description taken in conjunction with the provided drawings.

### BRIEF DESCRIPTION OF THE DRAWINGS

FIGS. 1a-1c are respectively a D-T₂ cross-plot showing oil, water and gas regions, and first integration of the cross-plot showing total signal intensity as a function of diffusion, and a second integration of the cross-plot showing total signal intensity as a function of T₂;

FIG. 2 depicts three distinct T₂ distributions obtained utilizing MRF processing of the data utilized to obtain the D-T₂ cross-plot of FIG. 1;

FIGS. 3a and 3b are respectively the D-T₂ cross-plot of FIG. 1 and a diffusion intensity plot showing diffusion intensity for different diffusion values at an identified T₂ value;

FIG. 4 is a D-T₂ plot showing fluid boundary curves;

FIGS. 4a-4c are respectively D-T₂ maps separately showing the fluid boundary curves shown in FIG. 4;

FIG. 5 is the D-T₂ cross-plot of FIG. 3a with the water-oil boundary and water-gas boundary taken from FIGS. 4a and 4b shown thereon;

FIG. 6 is the D-T₂ cross-plot of FIG. 1 with straight-line water-oil and water-gas boundaries shown thereon; and

FIG. 7 is a flow diagram of one embodiment of a method.

### DETAILED DESCRIPTION

The particulars shown herein are by way of example and for purposes of illustrative discussion of the examples of the subject disclosure only and are presented in the cause of providing what is believed to be the most useful and readily understood description of the principles and conceptual aspects of the subject disclosure. In this regard, no attempt is made to show details in more detail than is necessary, the description taken with the drawings making apparent to those skilled in the art how the several forms of the subject disclosure may be embodied in practice. Furthermore, like reference numbers and designations in the various drawings indicate like elements.

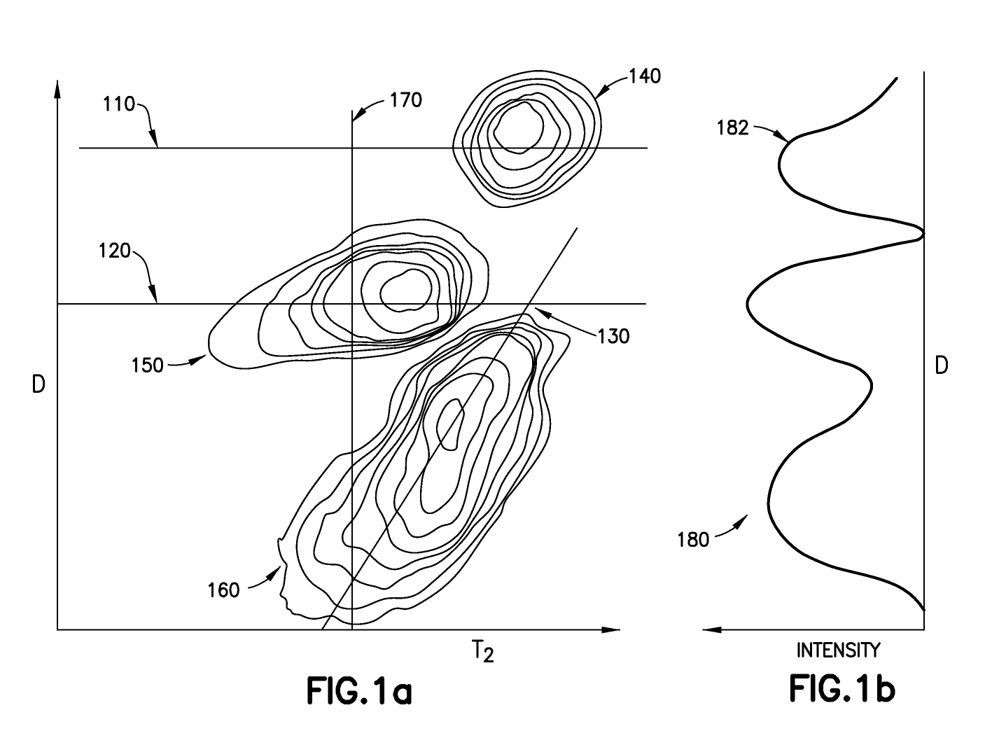

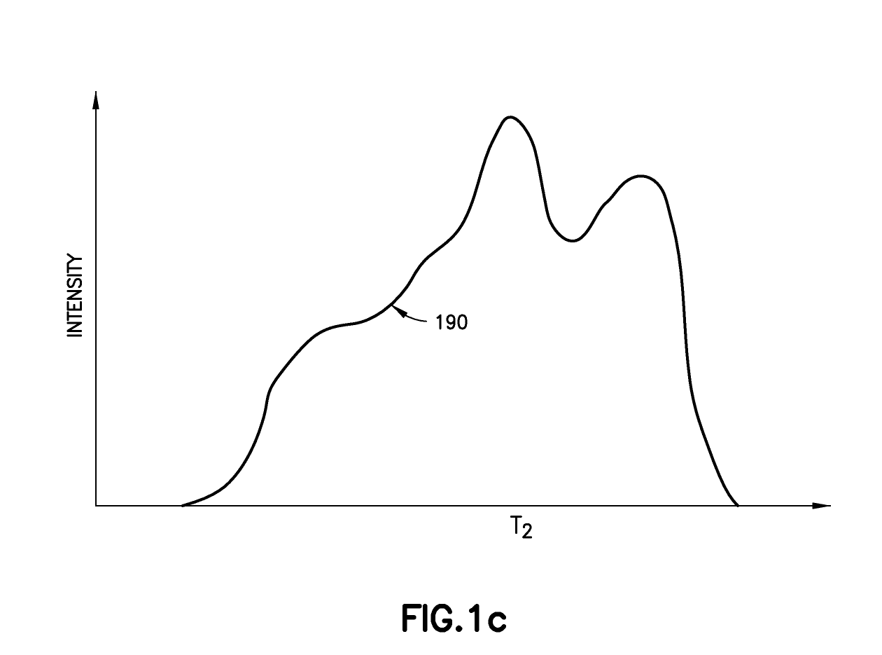

In NMR logging it is common to locate an NMR logging tool down a borehole, generate a sequence of diffusion editing pulses and pulses with particular spacings and echos, and acquire data that is a function of NMR diffusion (D), spin-lattice relaxation time (T₁) and spin-spin relaxation time (T₂) of the formation under investigation. It is also common to process the obtained data using a 2D or 3D Laplace inversion and to provide a D-T₂ map as shown in FIG. 1a. The map of FIG. 1a is a multidimensional plot and may be considered a three dimensional plot, where the diffusion as measured by the NMR logging tool is plotted on the vertical axis while the T₂ is plotted on a horizontal axis, forming a colored contour map where the signal intensity at each point is represented by the color of its contour. In the case of FIG. 1a, color is not shown, but the signal intensity is understood to increase as the circles or forms decrease in diameter. The common way of interpreting the map is to locate peaks by their location on the known diffusion lines, such as that of water and gas, and assign the peaks to the corresponding fluids. This enables a separation of the NMR signal, which contains contributions from oil, water, and gas, into separate contributions from each component which can be used to calculate various parameters, such as, by way of example, oil and water saturation.

In FIG. 1a, well known diffusion lines 110 (for gas), 120 (for water), and 130 (for oil) are drawn on the plot to help interpret the data. The D-T₂ map signal 140, falling on the gas line 110 is assigned to gas and the contour plot of the signal 140 is integrated in both T₂ and D domains to provide a gas signal. Similarly, the D-T₂ map signal 150 is assigned to the water and the D-T₂ map signal 160 to the oil.

In FIG. 1a, a line 170 of constant T₂ is drawn that passes through both oil and water signals. The line 170 corresponds to a constant T₂ but has varying diffusion constants.

The D-T₂ distribution in FIG. 1 can be projected over the diffusion side to generate a diffusion intensity plot 180 as seen in FIG. 1b, and also to project the distribution on the T₂ side to generate a T₂ intensity plot 190 as seen in FIG. 1c. Each point in the projection over the diffusion is the result of integrating the signal over the entire T₂ domain while the diffusion has been kept constant. This leads to a single curve 182 which shows the diffusion from the three fluids. Similarly when the map is projected onto the T₂ side, at each value of T₂ the entire diffusion is integrated, leading to a single number. This process, although useful, causes some loss of information due to integration.

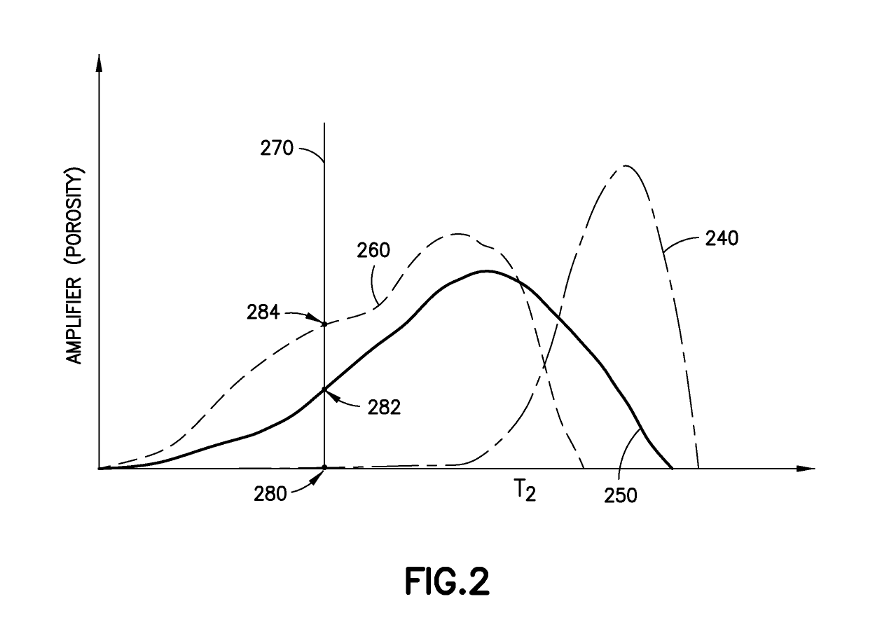

Turning to FIG. 2, results are seen of processing the acquired NMR data in order to obtain a graph of T₂ amplitude for each fluid constituent in the formation. In one embodiment, the NMR data is processed according to MRF processing such as described in previously incorporated U.S. Pat. No. 6,229,308 to Freedman, and in various papers such as Freedman, R. et al., “A New NMR Method of Fluid Characterization in Reservoir Rocks: Experimental Confirmation and Simulation Results”, SPE 75325 (2001), Freedman, R., et al., “Wettability, Saturation, and Viscosity Using the Magnetic Resonance Fluid Characterization Method and New Diffusion-Editing Pulse Sequences”, SPE 77397 (2002), Freedman, R., et al., “Wettability, Saturation, and Viscosity from NMR Measurements,” SPE 87340 (2003), and Freedman, R. and Heaton, N., “Fluid Characterization Using Nucelar Magnetic Resonance Logging”, Society of Petrophysicists and Well Log Analysts, pp. 241-250 May-June 2004, all of which are hereby incorporated by reference herein in their entireties. The MRF processing provides a T₂ distribution (signal intensity versus T₂) for each fluid in the pore space. Thus, in FIG. 2, three distinct T₂ distributions are provided, with curve 240 representing the gas porosity, curve 250 representing oil porosity, and curve 260 representing water porosity. In FIG. 2, line 270 corresponds to the same T₂ value shown by line 170 in FIG. 1a. The intersection of line 270 and curves 240, 250, 260 at points 280, 282 and 284 provide respectively the gas, oil and water content at that T₂. In the example shown, there is no gas contribution and 280 is zero. However, if the line 270 was drawn at larger T₂ values, there would have been an intersection with gas as well as oil and water.

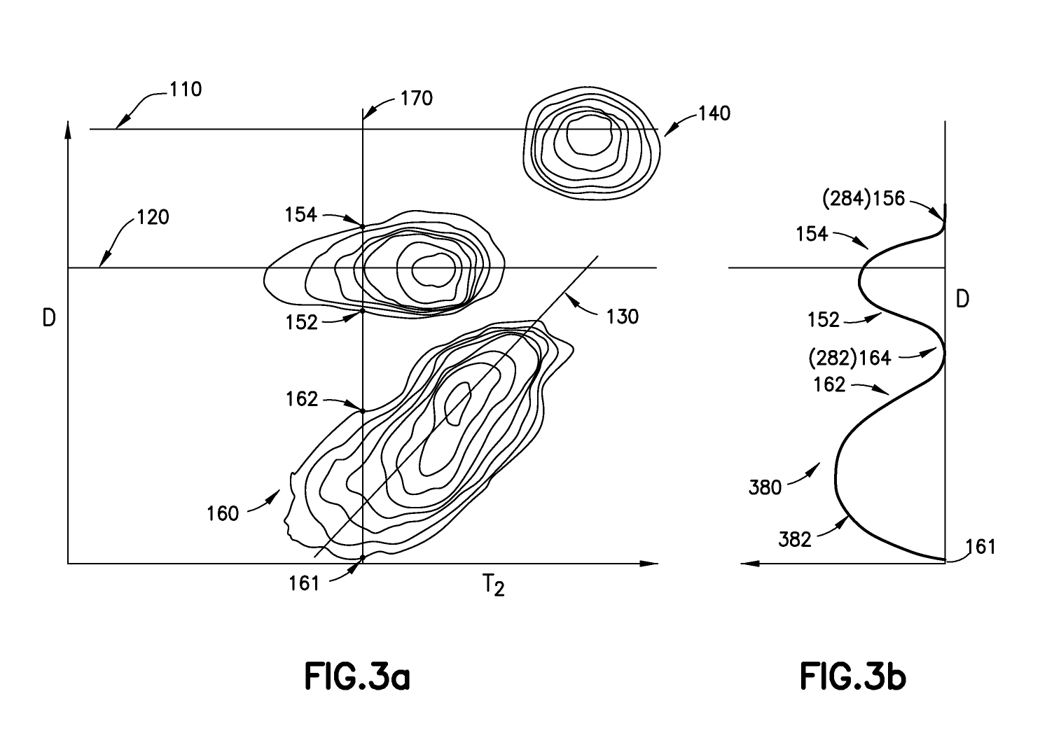

In one embodiment, and as seen with reference to FIGS. 3a and 3b, the D-T₂ distribution of FIG. 3a may be projected without integration over the D axis at individual values of T₂, e.g., the T₂ value shown by line 170. As explained hereinafter, the resulting curve 380 (FIG. 3b) may be integrated into three separate bins, each for one of the fluids in the rock. More particularly, as the line 170 of FIG. 3a is drawn from small to large Ds, the line 170 crosses the oil contours between the points 161 up to 162 for which the oil signal becomes very weak. The oil signal continues to decrease while the water signal starts to increase. The trend continues up to (or before) the point 152 where the line 170 touches the first intense water contour and eventually reaches the point 154 after which the water signal gradually approaches zero intensity. The signal intensity along the line 170 is projected without integration, and is shown as projection 380 of FIG. 3b. The intensity of the signal, 382, is plotted as a function of D while T₂ is kept constant. In one embodiment, the area under the curve 382 is integrated from point 161 to point 164 and is attributed to the oil; and the area under the curve from point 164 to point 156 is integrated and is attributed to the water. It should be appreciated that point 164 should correspond to point 282 from FIG. 2 and the point 156 should correspond to point 284 from FIG. 2. The net result for this T₂ value, T_{2,k}, is a set of two numbers Aₒ(T_{2,k}) and A_{w}(T_{2,k}); i.e., the amplitude for the oil signal at the given T₂ value, and the amplitude of the water signal at that T₂ value. When the lines 170 and 270 are drawn at other T₂ values where they intersect the signal from oil, water and gas, there would be an additional number, A_{g}(T_{2,k}) corresponding to the amplitude of the gas signal.

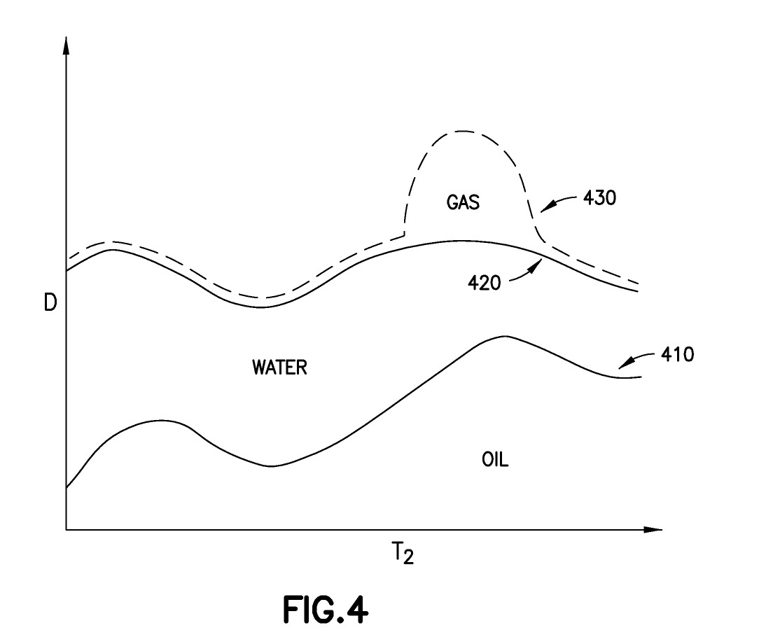

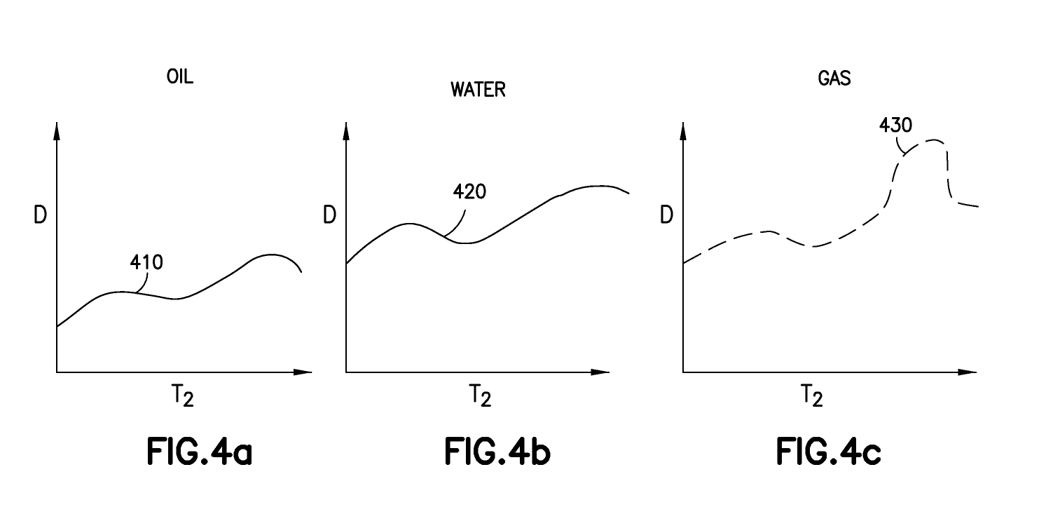

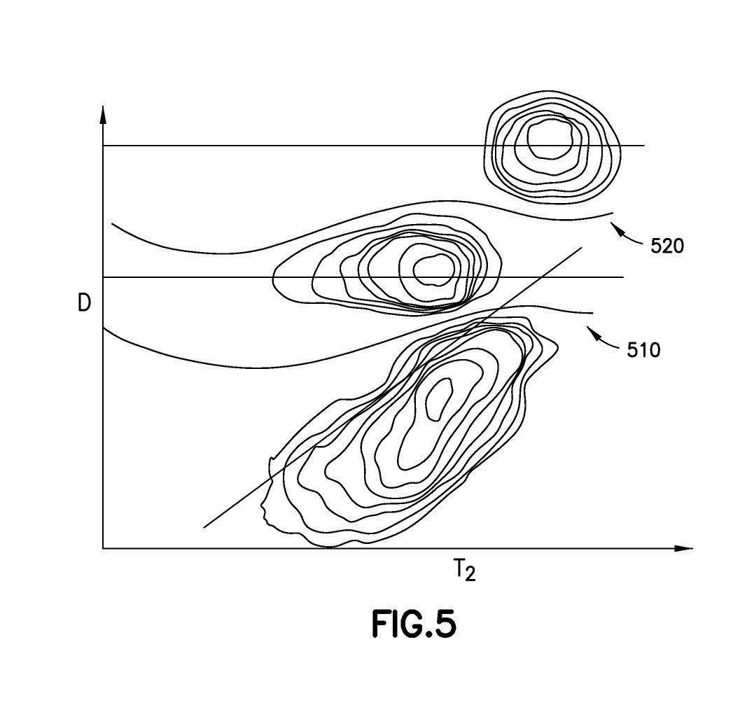

Repeating this process at different T₂ values, leads to a set of three numbers for each T₂ (some may be zero depending on the T₂ values). The data obtained, can be plotted as three curves 410, 420, 430 on a single D-T₂ plot, as shown in FIG. 4, with one curve for each fluid. The data can also be plotted on separate D-T₂ plots as shown in FIGS. 4a-4c. It is noted that in FIG. 4, the gas curve 430 is shown partly as a dotted line as there is no gas signal where the dotted line 430 matches curve 420. It is also noted that in FIG. 4, where the lines 430 and 420 diverge and indicate the presence of gas, there is no signal above the gas curve 430.

In the example of FIG. 3a (and FIG. 1a), the oil and water contours 160, 150 are distinct with no overlap, which happens in many cases. However, there are equally important cases where the contours overlap and it is not easy to choose points 164 and 156 in FIG. 3. In one embodiment, in this case, the upper limit of integration for oil is obtained from point 282 of FIG. 2.

In one aspect, the limits 161, 164 and 156 can be determined from the requirement that the integrals under the curve 382 (that represents fluids volumes) equate to values of points 280, 282 and 284 obtained from MRF processing. In other words, the integral of curve 382 of FIG. 3b, between the limits 161 and 164 will equal the volume of oil from point 282 of FIG. 2. Similarly, the integral of curve 382 between the limits 164 and 156 will equal the volume of water from point 284 of FIG. 2. Further, the integral of curve 382 above the limit 156 will equal the volume of gas from point 280 of FIG. 2. In one aspect, point 164 corresponds to the diffusion value above which there is no more oil signal (at that T₂), and point 156 corresponds to the diffusion value above which there is no more water signal (at that T₂).

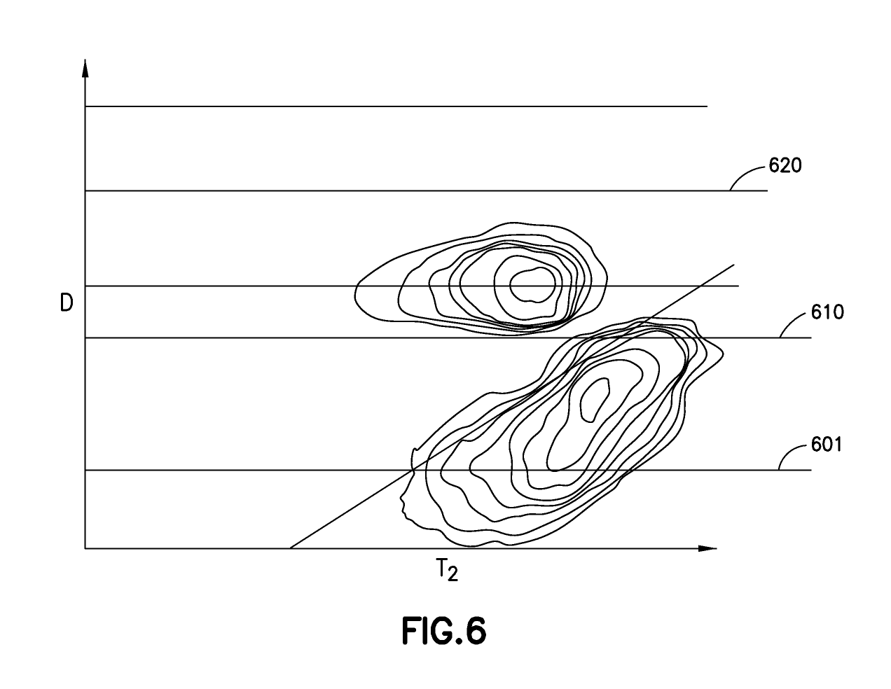

Once this exercise is repeated at different T₂ values, a set of numbers will be available which can be plotted as the D-T₂ map of FIG. 4 or the maps of FIGS. 4a-4c. In addition, the set of numbers can be plotted on the D-T₂ map of FIG. 3a (or FIG. 1a) resulting in what is seen in FIG. 5. Thus, FIG. 5 depicts a re-drawn FIG. 3a (or FIG. 1a) on which the boundary line (curve) 510 between water and oil, and boundary line (curve) 520 between water and gas are added.

According to one aspect, any point on the 510 curve is an cutoff for oil, implying that there is no water signal above that point. Similarly, any point on the 520 curve is a cutoff for water, implying there is no water signal above that point. However, for water, the 520 curve does not mean that any data below curve 520 is water; rather the lower bound for water is set by the oil curve 510. Therefore, the water cutoff is between curves 510 and 520.

In the embodiment of FIG. 5, the cutoff lines (curves) 510 and 520 vary as T₂ is varied and are not straight lines. In other embodiments, the cutoffs can be assumed (or approximated) to be straight lines. Thus, in one embodiment, straight line cutoffs using a fitting procedure may be generated by approximating curves 510 and 520 with straight lines using a least squares fit or other fitting technique. In another embodiment, different processing may be utilized to generate straight line separations between the oil, water, and gas phases. More particularly, in a situation where fluid saturations are known, the known fluid saturations can be used to place the two cutoff lines. According to this embodiment, a straight (horizontal) line, 601, is drawn on the D-T₂ map, as shown in FIG. 6, and the fluid volumes below and above the line are integrated. Initially the fluid volumes will not be equal to the known saturation levels. But the lines can be moved and the process repeated until the saturation levels are satisfied. The final cutoff lines are shown as 610 and 620 for oil and water.

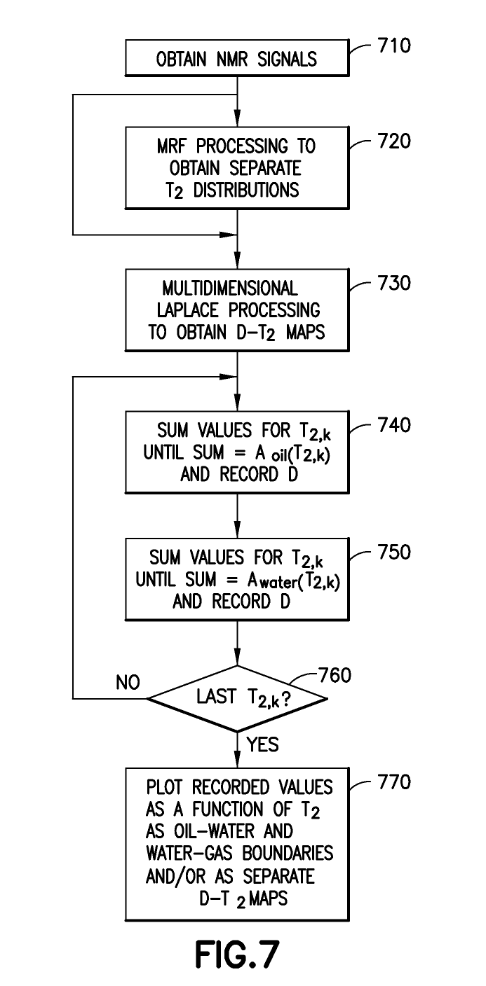

Turning to FIG. 7, an embodiment of a method for separating water and oil and optionally gas in multidimensional nuclear magnetic resonance (NMR) maps is seen. At 710, signals from an NMR tool (not shown) and that are a function of at least D, T₁ and T₂ are obtained. At 720, using MRF processing of the signals, oil, water and optionally gas T₂ distributions (such as in FIG. 2) are obtained. The distribution for oil may be denoted as Aₒᵢₗ(T_{2,k}), while the distribution for water may be denoted as A_{water}(T_{2,k}), and A_{gas}(T_{2,k}) may be denoted as the distribution for gas, where the index k denotes that T_{2,k} is discrete and spans the entire range of inverted T₂ values. At 730, the NMR signals are processed, e.g., using a multidimensional Laplace inversion, to obtain intensity values for a D-T2 mapping (as in FIG. 3a). At 740, for a specific T2 value (slice), T_{2,k}, the intensity values in the voxels of the mapping are summed starting from a lowest diffusion (D) value, until the sum is equal to Aₒᵢₗ(T_{2,k}), and the D value at which the sum equals Aₒᵢₗ(T_{2,k}) (i.e., a point of the oil-water boundary) is recorded for plotting. At 750, for that specific T₂ value, the intensity value in the voxels of the mapping above the oil-water boundary point are summed until the sum is equal to A_{water} (T_{2,k}), and the D value at which the sum equals A_{water}(T_{2,k}) (i.e., a point on the water-gas boundary) is recorded for plotting. If desired, for the same specific T₂ value, the remainder of the signal above the water-gas boundary may be considered the gas signal. At 760, a determination is made whether T₂ values have been processed. If not, summing is repeated at 740 and 750 for a different T2 value until T₂ values have been processed. Then, at 770, the D values recorded at 740 are plotted as a function of T₂ as an oil-water boundary (as in FIG. 5) and/or as a D-T₂ oil map (as curve 510 in FIG. 4a), and the D values recorded at 750 are plotted as a function of T₂ as an water-gas boundary (as curve 520 in FIG. 5) and/or as a D-T2 oil map (as in FIG. 4b). If desired, the D-T₂ map of the gas signal (as in FIG. 4c) may also be provided. Alternatively or additionally, the D values recorded at 740 and 750 may be further processed to obtain straight cutoff lines (e.g., by comparing fluid volumes above and below the lines to known fluid saturations), which may be plotted on a D-T₂ map or provided as determined D cut-off values.

In one aspect, multidimensional maps and/or cut-off values of the oil and water signals may be displayed on paper or on an electronic medium such as a computer screen.

According to one embodiment, the methods described above can be used to separate the oil and water along the diffusion direction with a D-T₂ map, but also with respect to other multidimensional maps such as a a D-T₁/T₂ map, a D-T₂-T₁/T₂ map, and a D-T₂-T₁ map. This is because T₁ information is obtained and preserved during processing and therefore a T₁/T₂ ratio can be calculated. Since the separation of oil and water according to the described methods is based along the diffusion direction, and T₁ information is not used to extract a boundary, there is an implicit assumption that the boundary is not dependent on T₁. Under this assumption, the boundary is the same in the slices for different T₁/T₂ ratios.

In one aspect, the oil-water boundary and water-gas boundary curves, lines or values may be useful in deriving other information regarding the earth formation under investigation. By way of example and not by way of limitation, the oil-water boundary and water-gas boundary curves, lines or values may be used to obtain determinations or estimates of wettability.

In another aspect, multidimensional maps showing oil-water boundary and water-gas boundary curves, lines or values may be useful in deriving other information regarding the earth formation under investigation. By way of example and not by way of limitation, the multidimensional maps showing oil-water boundary and water-gas boundary curves, lines or values may be used to obtain determinations or estimates of wettability.

In one aspect, the processing of NMR signals to obtain oil-water boundary and water-gas boundary curves, lines or values, or multidimensional maps showing the same involves the transformation of the NMR signals into a physical representation that may be seen and utilized.

In one aspect, some of the methods and processes described above, such as MRF processing and inverse Laplace transformed are performed by a processor. The term “processor” should not be construed to limit the embodiments disclosed herein to any particular device type or system. The processor may include a computer system. The computer system may also include a computer processor (e.g., a microprocessor, microcontroller, digital signal processor, or general purpose computer) for executing any of the methods and processes described above. The computer system may further include a memory such as a semiconductor memory device (e.g., a RAM, ROM, PROM, EEPROM, or Flash-Programmable RAM), a magnetic memory device (e.g., a diskette or fixed disk), an optical memory device (e.g., a CD-ROM), a PC card (e.g., PCMCIA card), or other memory device.

Some of the methods and processes described above, as listed above, can be implemented as computer program logic for use with the computer processor. The computer program logic may be embodied in various forms, including a source code form or a computer executable form. Source code may include a series of computer program instructions in a variety of programming languages (e.g., an object code, an assembly language, or a high-level language such as C, C++, or JAVA). Such computer instructions can be stored in a non-transitory computer readable medium (e.g., memory) and executed by the computer processor. The computer instructions may be distributed in any form as a removable storage medium with accompanying printed or electronic documentation (e.g., shrink wrapped software), preloaded with a computer system (e.g., on system ROM or fixed disk), or distributed from a server or electronic bulletin board over a communication system (e.g., the Internet or World Wide Web).

Alternatively or additionally, the processor may include discrete electronic components coupled to a printed circuit board, integrated circuitry (e.g., Application Specific Integrated Circuits (ASIC)), and/or programmable logic devices (e.g., a Field Programmable Gate Arrays (FPGA)). Any of the methods and processes described above can be implemented using such logic devices.

In one aspect, the methods described may be applied to geological formations downhole, or uphole on rock or core samples. Where the methods are carried out with downhole NMR tools, the processing of the obtained signals may be carried out downhole and/or uphole.

Although only a few examples have been described in detail above, those skilled in the art will readily appreciate that many modifications are possible in the examples without materially departing from this subject disclosure. Thus, by way of example only, and not by way of limitation, while various embodiments show the provision of oil-water and water-gas boundaries, the number of boundaries and types of boundaries shown may be different. For example, depending upon the number of fluids that are present and that generate distinct NMR signals, a single boundary (e.g., oil-water, or water-gas, or oil-gas) may be shown, or more than two boundaries may be shown. Also, while methods have been described that involve processing the NMR signals to obtain separate oil and water T₂ intensity distributions utilizing MRF processing (which uses global inversion processing of a model having a plurality of components for an oil phase and a water or brine phase), it will be appreciated that other methods of separating the T₂ responses from different fluids may be utilized such as by way of example, differential spectrum, shift spectrum, enhanced diffusion, and dual-wait-time dual-echo spacing methods (see Sun, Boqin, and Dunn, Keh-Jim, “NMR Inversion Methods for Fluid Typing”, SPWLA 44^{th} Annual Logging Symposium, Jun. 22-25, 2003). Accordingly, all such modifications are intended to be included within the scope of this disclosure as defined in the following claims. In the claims, means-plus-function clauses are intended to cover the structures described herein as performing the recited function and not only structural equivalents, but also equivalent structures. Thus, although a nail and a screw may not be structural equivalents in that a nail employs a cylindrical surface to secure wooden parts together, whereas a screw employs a helical surface, in the environment of fastening wooden parts, a nail and a screw may be equivalent structures. It is the express intention of the applicant not to invoke 35 U.S.C. §112, paragraph 6 for any limitations of any of the claims herein, except for those in which the claim expressly uses the words ‘means for’ together with an associated function.

What is claimed is:

1. A method utilizing nuclear magnetic resonance (NMR) signals resulting from an investigation of a sample containing at least two different fluids, comprising:
processing the NMR signals to obtain a multidimensional mapping including at least diffusion (D) and spin-spin relaxation (T₂) axes;
finding at least one boundary between the at least two different fluids; and
plotting the at least one boundary on the multidimensional mapping and displaying the same.

2. The method according to claim 1, wherein:
the at least two different fluids includes oil and water, and the at least one boundary includes a water-oil boundary.

3. The method according to claim 2, wherein:
the finding at least one boundary comprises,
processing the NMR signals to obtain separate oil and water T₂ intensity distributions, and for each T₂ of a range of T₂ values, summing a plurality of the intensity values over a plurality of D values until a first sum equals the oil intensity value for that T₂.

4. The method according to claim 2, wherein:
the at least two different fluids includes oil, water, and gas, and the at least one boundary further includes a water-gas boundary, and
the finding at least one boundary comprises processing the NMR signals to obtain separate oil and water T₂ intensity distributions, and for each T₂ of a range of T₂ values, summing a plurality of the intensity values over a plurality of D values until a first sum equals the oil intensity value for that T₂ and until a second sum equals the water intensity value for that T₂, in order to obtain oil and water cut-off points.

5. The method according to claim 4, wherein:
the plotting comprises plotting the boundary as other than a straight line.

6. The method according to claim 4, wherein:
the plotting comprises plotting the boundary as a straight line.

7. The method according to claim 4, wherein:
the processing the NMR signals to obtain separate oil and water T₂ intensity distributions comprises processing according to magnetic resonance fluid (MRF) processing.

8. The method according to claim 1, wherein:
the finding comprises integrating fluid volumes from the multidimensional mapping and matching the fluid volumes to known fluid saturations, wherein the plotting comprises plotting the at least one boundary as a straight line.

9. The method of investigating a sample, comprising:
obtaining nuclear magnetic (NMR) signals resulting from an NMR investigation of the sample;
processing the NMR signals to obtain separate oil and water T₂ intensity distributions;
processing the NMR signals to obtain intensity values for a multidimensional mapping;
for a given T₂ value and repeating for a range of T₂ values, starting with a lowest D level and increasing therefrom, summing intensity values of the multidimensional mapping until a sum is obtained equal to the oil intensity for that T₂, thereby obtaining an oil cut-off value point for each T₂ value;
for the given T2 value and repeating for the range of T₂ values, starting with a next D level above the oil cut-off value point and increasing therefrom, summing intensity values of the multidimensional mapping until a sum is obtained equal to the water intensity for that T₂, thereby obtaining a water cut-off value point for each T₂ value;
using the oil cut-off value point for each the T₂ value and the water cut-off value point for each the T₂ value, generating at least one of a multidimensional map and cut-off values of oil and water signals, and displaying the same.

10. The method according to claim 9, wherein:
the generating comprises generating a D-T₂ map with an oil-water boundary.

11. The method according to claim 10, wherein:
the D-T₂ map includes a water-gas boundary.

12. The method according to claim 10, wherein:
the oil-water boundary is other than a straight line.

13. The method according to claim 11, wherein:
the oil-water boundary and the water-gas boundary are other than straight lines.

14. A method according to claim 9, wherein:
the generating comprises generating an oil D-T₂ map and a separate water D-T₂ map.

15. The method according to claim 14, wherein:
the generating further comprises generating a separate gas D-T₂ map.

16. The method according to claim 9, wherein:
the generating comprises generating the cut-off values of oil and water signals.

17. The method according to claim 9, wherein:
the processing the NMR signals to obtain separate oil and water T₂ intensity distributions comprises processing according to magnetic resonance fluid (MRF) processing.

18. The method according to claim 9, wherein:
the sample is a subsurface formation.

19. The method of investigating a formation traversed by a borehole, comprising:
locating a nuclear magnetic resonance (NMR) tool in the borehole and generating an NMR pulse sequence therewith;
detecting NMR signals that are a function of diffusion (D), spin-lattice relaxation (T₁) and spin-spin relaxation (T₂);
processing the NMR signals to obtain separate oil and water T₂ intensity distribution, and to obtain intensity values for a multidimensional mapping incorporating at least diffusion (D) and spin-spin relaxation (T₂) information;
for each T₂ of a range of T₂ values, summing a plurality of the intensity values over a plurality of D values until a first sum equals the oil intensity value for that T₂ and until a second sum equals the water intensity value for that T₂, in order to obtain oil and water cut-off points; and
from the oil and water cut-off points, generating at least one of a multi-dimensional map and cut-off values of oil and water signals, and displaying the same.

20. The method according to claim 19, wherein:
the generating comprises generating a D-T₂ map with an oil-water boundary and with a water-gas boundary.

21. The method according to claim 20, wherein:
the oil-water boundary and the water-gas boundary are other than straight lines.

22. The method according to claim 19, wherein:
the generating comprises generating an oil D-T₂ map and a separate water D-T₂ map.

23. The method according to claim 22, wherein:
the generating further comprises generating a separate gas D-T₂ map.

24. The method according to claim 11, wherein:
the processing the NMR signals to obtain separate oil and water T₂ intensity distributions comprises processing according to magnetic resonance fluid (MRF) processing.
